(19) United States
(12) Patent Application Publication
(10) Pub. No.: US 2012/0083127 A1
(43) Pub. Date: Apr. 5, 2012

(54) METHOD FOR FORMING A PATTERN AND A SEMICONDUCTOR DEVICE MANUFACTURING METHOD

(75) Inventors: Robert D. Clark, Livermore, CA (US); Eric J. Strang, Gilbert, AZ (US)

(73) Assignee: TOKYO ELECTRON LIMITED, Tokyo (JP)

(21) Appl. No.: 12/895,507

(22) Filed: Sep. 30, 2010

(51) Int. Cl. H01L 21/302

(52) U.S. Cl. 438/703; 257/E21.214

(57) ABSTRACT

A method for forming a fine pattern on a substrate includes providing a substrate including a material with an initial pattern formed thereon and having a first line width, performing a self-limiting oxidation and/or nitridation process on a surface of the material and thereby forming an oxide, a nitride, or an oxynitride film on a surface of the initial pattern, and removing the oxide, nitride, or oxynitride film. The method further includes repeating the formation and removal of the oxide, nitride, or oxynitride film to form a second pattern having a second line width that is smaller than the first line width of the initial pattern. The patterned material can contain silicon, a silicon-containing material, a metal, or a metal-nitride, and the self-limiting oxidation process can include exposure to vapor phase ozone, atomic oxygen generated by non-ionizing electromagnetic (EM) radiation, atomic nitrogen generated by ionizing or non-ionizing EM radiation, or a combination thereof.

### FIELD OF THE INVENTION

The present invention relates to a method of forming a pattern and a semiconductor device manufacturing method, and specifically to a method of forming a pattern and a semiconductor device manufacturing method that can be applied to cases where a pattern, such as a line-and-space pattern, is formed on a material in the process of manufacturing various semiconductor devices.

### BACKGROUND OF THE INVENTION

In the process of manufacturing various semiconductor devices, a photolithography technique is used to perform patterning of a resist film formed on a target substrate surface, in order to form a resist pattern by subjecting the resist film to light exposure and development. Then, etching is performed using the resist pattern as a mask to form a pattern, such as a line-and-space pattern, on the target substrate. For example, in the process of manufacturing a poly-crystalline silicon gate electrode, a resist pattern is used as a mask while dry etching is performed with plasma of a CF-family gas on a poly-crystalline silicon layer formed on a semiconductor wafer. However, when a pattern is formed by dry etching with plasma, it is difficult to control the shape of the pattern.

In the case of dry etching, other problems have been observed, including plasma damage, and surface roughening of a silicon surface and/or an underlying film. The problems with surface roughness and damaged layers may manifest as an increase in junction leakage in semiconductor devices. As integrated circuits become smaller, photolithography alone is not sufficient to create the smallest features needed for advanced devices. Instead, etch processes are used to shrink features to appropriate sizes. One example is gate trimming that is done to reduce the gate length of transistors to dimensions below the smallest printed feature geometry.

As IC's (Integrated Circuits) move to 3 dimensional transistor structures, such as a 3D MOSFET (metal-oxide-semiconductor field-effect-transistors) or finFET, the fins or channels will need to be thinned significantly while maintaining a reasonable geometry. The use of a process of this type could also be extremely valuable in the production of advanced Microelectromechanical Machines (MEMS). One disadvantage of gate thinning by traditional etching is feature rounding and distortion that accompanies the process. As features become smaller, even with optical proximity correction (OPC) and other image enhancing techniques, it is impractical or sometimes impossible to print the desired features.

### SUMMARY OF THE INVENTION

Embodiments of the invention describe a method for pattern formation and particularly a method for performing complex pattern formation in manufacturing various semiconductor devices. In some examples, embodiments of the invention are suitable for manufacturing a transistor having a three-dimensional structure that requires complex pattern formation.

According to one embodiment, a pattern forming method is described that includes providing a substrate including a material with an initial pattern formed thereon and having a first line width, performing a self-limiting oxidation, nitridation, or oxidation and nitridation process on a surface of the material inside a process chamber of a processing apparatus and thereby forming an oxide, nitride, or oxynitride film on a surface of the initial pattern, wherein the self-limiting oxidation, nitridation, or oxidation and nitridation process includes exposing the surface of the material to vapor phase ozone, atomic oxygen generated by non-ionizing electromagnetic (EM) radiation, atomic nitrogen generated by ionizing or non-ionizing EM radiation, or a combination thereof. The method further includes removing the oxide, nitride, or oxynitride film, where the pattern forming method is arranged to repeatedly perform formation of the oxide, nitride, or oxynitride film and removal of the oxide, nitride, or oxynitride film so as to form a second pattern having a second line width that is smaller than the first line width of the initial pattern.

### BRIEF DESCRIPTION OF THE DRAWINGS

A more complete appreciation of the present invention and many attendant advantages thereof will be readily obtained as the same becomes better understood by reference to the following detailed description when considered in connection with the accompanying drawings, wherein:

FIG. 1 is a flow chart showing a method of forming a pattern according to an embodiment of the invention;

FIGS. 2A-2E are schematic sectional views of processing steps for forming a fine pattern by repeatedly performing self-limiting surface oxidation, nitridation, or oxidation and nitridation and oxide, nitride, or oxynitride film removal according to an embodiment of the invention;

FIGS. 3A and 3B schematically show oxide film thickness as a function of oxidation time for self-limiting oxidation conditions according to embodiments of the present invention;

FIG. 4A is a perspective view showing the external appearance of a three-dimensional MOSFET;

FIG. 4B is a perspective view showing the fin structure of the three dimensional MOSFET;

FIG. 5 is a schematic diagram of a processing system containing a non-ionizing electromagnetic (EM) radiation source for performing a self-limiting oxidation, nitridation, or oxidation and nitridation process according to one embodiment of the invention;

FIG. 6 is a schematic diagram of another processing system containing a non-ionizing radiation source and vapor phase ozone source for performing a self-limiting oxidation, nitridation, or oxidation and nitridation process according to one embodiment of the invention; and

FIG. 7 schematically shows a chemical oxide removal (COR) processing apparatus for oxide film removal according to one embodiment of the invention.

### DETAILED DESCRIPTION OF SEVERAL EMBODIMENTS

Embodiments of the invention describe methods to thin or shrink features made of Si, Si-containing materials (e.g., SiN), metals (e.g., Al), or metal nitrides. The method combines self-limited, highly conformal, oxidation, nitridation, or oxidation and nitridation with subsequent oxide, nitride, or oxynitride film removal (e.g., COR), performed in alternating sequences, to thin or shrink a feature. The methods provide an etch process with digital control over material removal that includes excellent controllability with minimal rounding or distortion.

In one embodiment, a feature is patterned using traditional lithography and a standard etch process is designed to create a feature larger than the desired feature that has the desired shape. The feature is then further processed using a self-limited oxidation and/or nitridation process that can include exposure to vapor phase ozone (VPO), exposure to atomic oxygen generated by non-ionizing electromagnetic (EM) radiation (e.g., ultraviolet radiation dissociation of O₂ gas (UVO₂)), exposure to atomic nitrogen generated by ionizing or non-ionizing EM radiation (e.g., ultraviolet radiation dissociation of a nitrogen-containing gas), or a combination thereof. After purging or evacuation, the oxide, nitride, or oxynitride film is removed using an oxide, nitride, or oxynitride film removal process. After purging or evacuating again, the process is repeated until the desired feature size is reached.

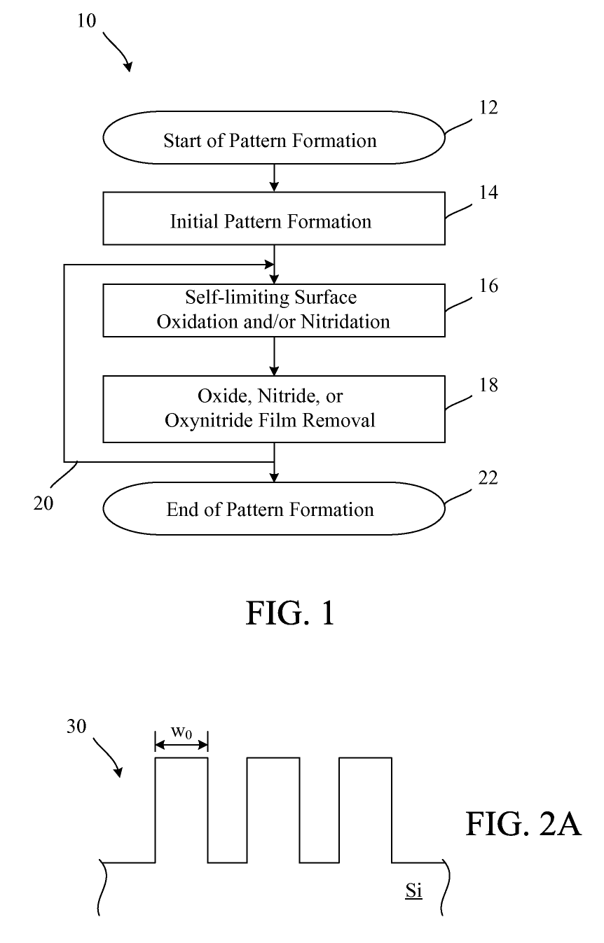

FIG. 1 is a flow chart showing a method of forming a pattern according to an embodiment of the invention. For brevity, the method is described for trimming a Si material but embodiments of the invention may also be applied to other Si-containing materials, metals, metalloids and metal nitrides, for example SiGe, Ge, GaN, GaAs, InGaAs, Al, TiN, TaN, W, TiAlN, TaAlN, NiSi, WSi, CoSi, and others. The process 10 of pattern formation starts in step 12. An initial pattern having a first line width is formed on a silicon surface of a substrate in step 14. This initial pattern may be formed by dry etching through a resist mask with a pattern formed by a photolithography technique.

Thereafter, a self-limiting oxidation and/or nitridation process is performed in step 16 on the substrate with the initial pattern formed thereon to oxidize and/or nitride the silicon surface to form a silicon oxide, silicon nitride, or silicon oxynitride film. In non-limiting examples, the self-limiting oxidation and/or nitridation process may include a UVO2 process, a VPO process, a plasma induced dissociation of a nitrogen-containing gas process, a remote plasma induced dissociation of a nitrogen-containing gas, or a combination thereof. For example, the plasma induced dissociation process of a nitrogen-containing gas may include a SPA (slotted plane antenna) nitridation process.

Thereafter, the silicon oxide, nitride, or oxynitride film thus formed is removed in step 18. The oxide, nitride, or oxynitride film removal process can be performed by any method capable of preferentially removing the silicon oxide, nitride, or oxynitride film from the unreacted portion of the Si material. Accordingly, the oxide, nitride, or oxynitride film removal is not limited to a specific method, but may be selected from one or more of the following methods, for example: (1) a wet etching process using diluted hydrofluoric acid, (2) a vapor etching process containing a hydrofluoric acid vapor atmosphere, (3) a COR process, nitride, or oxynitride removal process arranged to expose the silicon oxide, nitride, or oxynitride film to a reactive gas containing HF and optionally NH₃ to form a reaction product and then to remove the reaction product by heating, and (4) an NOR (Native Oxide Removal) process arranged to expose the silicon oxide film to active species containing H, N, and NF₃ to form a reaction product and then to remove the reaction product by heating. Methods based on (3) the COR process and (4) the NOR process described above are disclosed in, for example, Jpn. Pat. No. 2501295 and Jpn. Pat. Appln. KOKAI Publication No. 2000-208498, respectively, and are known as methods for removing a native oxide film formed on a Si surface.

In the pattern forming method according to embodiments of the invention, the self-limiting oxidation and/or nitridation process in step 16 and the oxide, nitride, or oxynitride film removal process in step 18 are repeated a desired number of times as indicated by process arrow 20. Consequently, the initial pattern having the first line width is transformed into a second pattern having a second line width that is smaller than the first line width.

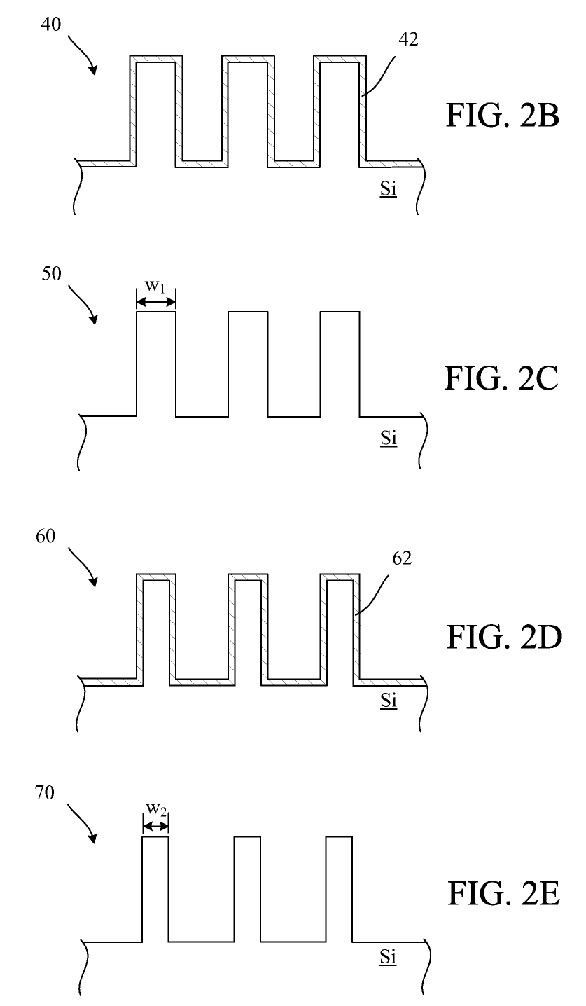

FIGS. 2A-2E are schematic sectional views of processing steps for forming a fine pattern by repeatedly performing self-limiting surface oxidation, nitridation, or oxidation and nitridation, and oxide, nitride, or oxynitride film removal according to an embodiment of the invention. As shown in FIG. 2A, in the initial stage, the surface of a wafer is provided with an initial pattern 30 containing silicon (poly-crystalline silicon, amorphous silicon, or single-crystalline silicon) and having a first line width w₀. A self-limiting oxidation and/or nitridation process is performed on the silicon surface having the initial pattern 30 to form an oxidized and/or nitrided pattern 40 containing a silicon oxide, nitride, or oxynitride film 42, as shown in FIG. 2B.

Next, as shown in FIG. 2C, the silicon oxide, nitride, or oxynitride film 42 is removed by an oxide, nitride, or oxynitride film removal process, for example by any of the methods (1)-(4) described above. The oxide, nitride, or oxynitride film removal process forms an intermediate pattern 50 having an intermediate line width w₁ that is smaller than the first line width w₀.

Then, a self-limiting oxidation and/or nitridation process is repeated on the silicon surface having the intermediate pattern 50 in the same way as described above to form a silicon oxide, nitride, or oxynitride film 62, as shown in FIG. 2D. Then, the silicon oxide, nitride, or oxynitride film 62 is removed in the same way as described above. The self-limiting oxidation and/or nitridation process, and oxide, nitride, or oxynitride film removal process are sequentially repeated a desired number of times, for example 2 to 30 times, 2 to 20 times, or 2 to 10 times, to form a second pattern 70 having a second line width w₂ that is smaller than the intermediate line width w₁. This is schematically shown in FIG. 2E. By repeating the step of forming an oxide, nitride, or oxynitride film in an oxidation and/or nitridation process of patterned silicon surface and the step of removing the oxide, nitride, or oxynitride film, the pattern line width can be reduced to 100 nm or less, to 20 nm or less, or 10 nm or less, for example.

Some embodiments of the invention utilize a self-limiting oxidation and/or nitridation process with no ion exposure to the surface to controllably form silicon oxide, nitride, or oxynitride films (i.e., films 42 and 62) with a well-defined and repeatable thickness. In the exemplary case of oxide films, unlike many plasma-based oxidation methods and high-temperature oxidation methods, embodiments of the invention describe a self-limiting oxidation process that does not have the disadvantages of ion exposures and is tailored towards advanced integrated process that require low substrate temperatures. The basic mechanism in the dry oxidation process is oxidation of the Si pattern surface and subsequent diffusion of an oxidizing species through the formed oxide layer and the reaction of the oxidizing species with the Si pattern at the oxide/Si substrate interface. In a self-limiting oxidation process, the rate of oxidation decreases as the thickness of the oxide layer increases, until an oxide film with a final thickness is formed. The self-limiting nature of the oxidation process is likely due to hindered diffusion of the oxidizing species through the existing oxide film to the oxide/Si substrate interface. The final thickness of the oxide film is a function of the concentration of the oxidation species in the oxidation environment, substrate temperature, and the material of the initial pattern.

For a Si fin, the process described in embodiments of the invention results in thinning of the fin without reducing its height since the Si substrate and the top of the fin are etched the same amount. In one example, an initial Si pattern can have a height of about 80 nm and a width w₀ of about 60 nm. Removal of ˜1.2 nm if Si per cycle results in an etched film having a height of about 80 nm but a width of 36 nm (60−2×10×1.2). Thus, embodiments of the invention provide an etching method with digital control over material removal that includes excellent controllability with minimal rounding or distortion.

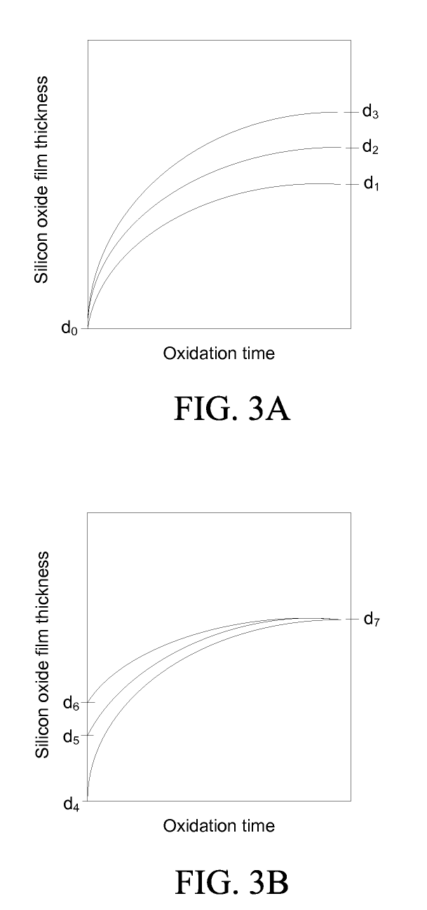

FIGS. 3A and 3B schematically show oxide film thickness as a function of oxidation time for self-limiting oxidation conditions according to embodiments of the invention. In order to achieve properties of self-limiting oxidation, the oxidation ambient should form an oxidation barrier on the pattern and further oxidation of the pattern is stopped once a self-limiting oxide thickness is reached. In a self-limiting oxidation process, the oxide growth rate (and the resulting final oxide film thickness) can be reduced/increased by decreasing/increasing the partial pressure of the oxidation species in the process gas and in the process chamber. In addition, the oxide growth rate can be reduced/increased by lowering/increasing the substrate temperature.

FIG. 3A schematically shows oxide film thickness as a function of oxidation time for different self-limiting oxidation conditions. The different self-limiting oxidation conditions in FIG. 3 can be applied to Si substrates having an initial oxide thickness d₀. The initial oxide thickness d₀ can be zero or greater than zero but less than the final desired silicon oxide thicknesses d₁, d₂, or d₃. The different self-limiting oxidation conditions form silicon oxide films with different thicknesses d₁, d₂ and d₃. The different self-limiting oxidation conditions can include different partial pressures of the oxidation species and/or different substrate temperatures.

FIG. 3B schematically shows silicon oxide film thickness as a function of oxidation time for the same self-limiting oxidation conditions but different initial oxide thicknesses d₄-d₆. Regardless of the initial oxide thicknesses d₄-d₆, the final oxide thickness d₇ is the same for all the substrates. This demonstrates the ability of the method to start with substrates that contain initial oxide films (e.g., a chemical or native oxide film), prior to growing a new oxide film, as long as the initial oxide thickness is less than the desired final oxide thickness. This can remove the need for stripping the initial oxide film prior to performing the self-limiting oxidation process. Furthermore, in a self-limiting oxidation process, it has been observed that an oxide film grows faster in regions where the oxide film is relatively thin, relative to substrate regions that contain a relatively thicker oxide film. This enables formation of an oxide film with high thickness uniformity over the entire substrate, whether or not the initial oxide film has high thickness uniformity. Further, embodiments of the invention are capable of reducing surface roughness of initial patterns (e.g., surface roughness of 0.2 to 1 nm) through preferential removal of oxidized surface roughness.

Next, an exemplary semiconductor device will be described, wherein a patterning method according to embodiments of the invention may be applied to a process for manufacturing the semiconductor device. The pattern forming method may be used in sub-micron semiconductor manufacturing to produce finer pattern features than are easily obtainable using conventional photolithography techniques. For example, the patterning method can be applied to fabrication of transistors having three-dimensional structures, such as a fin structure and a double gate structure. Such transistors having three-dimensional structures are being considered as alternatives to conventional planar MOS transistors, along with miniaturization of design rules due to an increase in the integration level and operation speed of LSIs.

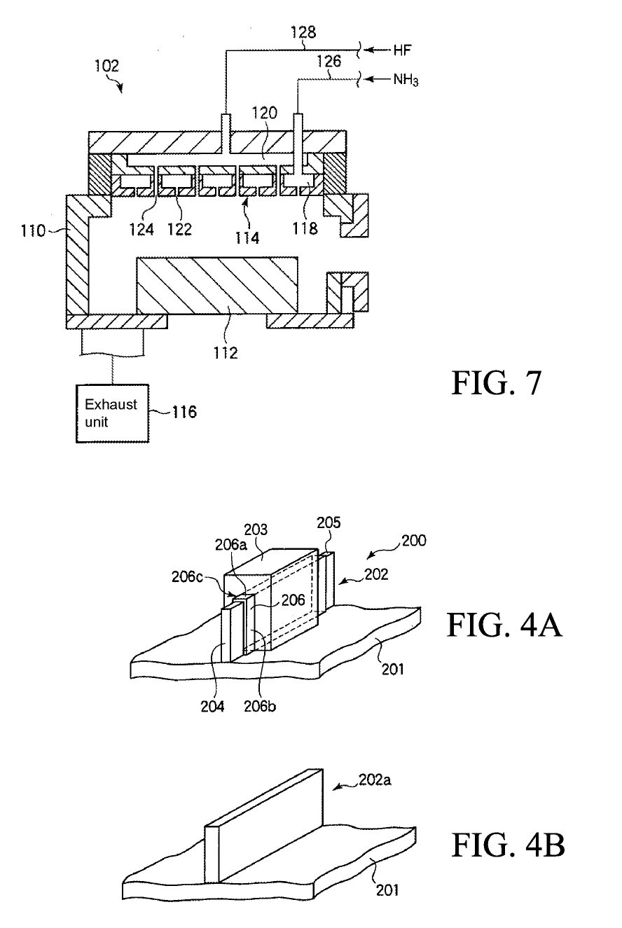

FIG. 4A is a perspective view showing the external appearance of a three-dimensional MOSFET having a fin structure, as an example of a three-dimensional device. The MOSFET 200 has a symmetric three gate structure where the gate overlaps the two sides and the top of the fin. The fin structure includes a silicon wall 202 formed on an underlying film 201, such as a SiO₂ film, and having a fin shape or raised feature. The three-dimensional structure is formed such that the silicon wall 202 is partly covered with a gate insulating film 206, and a gate electrode 203 is further formed on the gate insulating film 206. The gate insulating film 206 formed on the surface of the silicon wall 202 is covered with the gate electrode 203 on three sides, i.e., the top portion 206a and opposite wall surface portions 206b and 206c, thereby forming a transistor having a three-gate structure. The opposite extending portions of the silicon wall 202 with the gate electrode 203 interposed there between serve as a source 204 and a drain 205, and the transistor is arranged such that an electric current flows between the source and drain. Since the three-gate structure can control the channel region of the MOSFET by use of the three gates, it provides a better performance in preventing a short channel effect and is well suited for miniaturization and integration for the 32-nm node generation or smaller, compared to the conventional planar MOSFETs that control the channel region using a single gate.

FIG. 4B is a perspective view showing the fin structure of the three dimensional MOSFET 200 in FIG. 4A. The MOSFET 200 structure may be manufactured as follows. For example, a silicon layer is formed (e.g., by CVD) on an underlying film 201, such as an SiO₂ film, and then etching is performed using a mask that has a pattern formed thereon by a photolithography technique, to form a silicon wall 202a. Although FIG. 4B shows only one silicon wall 202a, a plurality of parallel silicon walls 202a may be used to form a semiconductor device.

Thereafter, the silicon wall 202a may be further trimmed by repeatedly performing the sequence of step 16 (self-limiting surface oxidation) and step 18 (oxide film removal step) in FIG. 1 to form a silicon wall 202 having a predetermined line width. Then, a gate insulating film 206 (e.g., a silicon oxide film) may be formed by using a self-limiting surface oxidation process using an oxidizing atmosphere on the surface of the silicon wall 202 with the desired line width pattern formed thereon. Alternately, an oxidation process, nitridation process, or an oxidation and nitridation process may be performed on the surface of the silicon wall 202, for example, to form a silicon oxide film (SiO₂ film), a silicon nitride film (SiN), or a silicon oxynitride film (SiON film). The oxidation process, nitridation process, or oxidation and nitridation process may be performed by use of a plasma processing apparatus, for example using a capacitively coupled plasma (CCP), an inductively coupled plasma (ICP), a surface reflection wave plasma, or a magnetron plasma.

Then, a poly-crystalline silicon layer is formed by, e.g., CVD (chemical vapor deposition), to cover the silicon wall 202, and etching is performed using a mask that has a pattern formed thereon by a photolithography technique, to form a poly-crystalline silicon gate electrode 203, thereby completing the MOSFET 200. Alternatively, the gate electrode 203 may contain or consist of other Si-containing materials, metals, metalloids and metal nitrides, for example SiGe, Ge, GaN, GaAs, InGaAs, Al, TiN, TaN, W, TiAlN, TaAlN, NiSi, WSi, CoSi, and others.

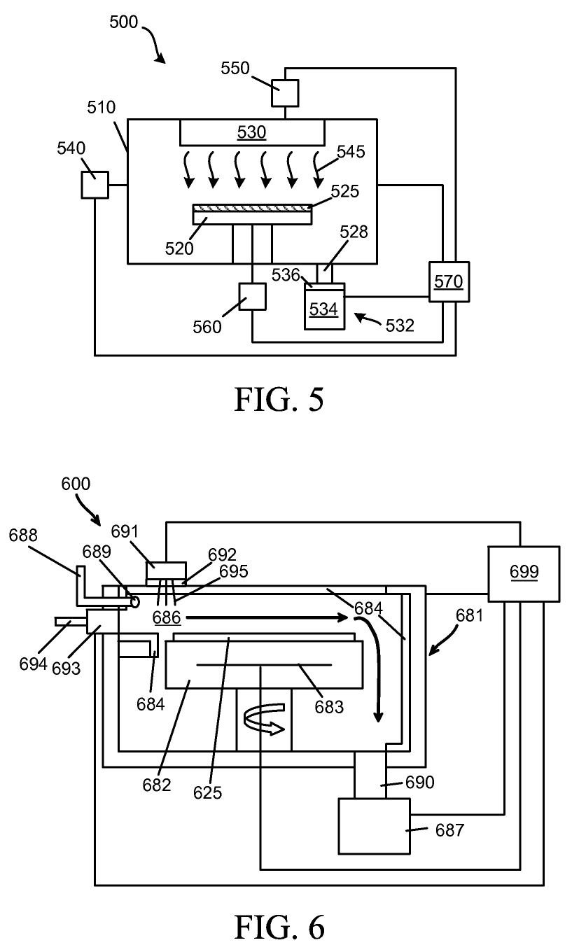

FIG. 5 is a schematic diagram of a processing system containing a non-ionizing electromagnetic radiation source for performing a self-limiting oxidation, nitridation, or oxidation and nitridation process according to one embodiment of the invention. The radiation source can be a UV (ultraviolet) radiation source or a visible light radiation source, for example. The processing system 500 contains a process chamber 510 having a substrate holder 520 configured to support a substrate 525. The process chamber 510 further contains an electromagnetic radiation assembly 530 for exposing the substrate 525 and a process gas in the process chamber to electromagnetic radiation. Additionally, the processing system 500 contains a power source 550 coupled to the electromagnetic radiation assembly 530, and a substrate temperature control system 560 coupled to substrate holder 520 and configured to elevate and control the temperature of substrate 525. A gas supply system 540 is coupled to the process chamber 510, and configured to introduce a process gas to process chamber 510. For example, the process gas can include an oxygen-containing gas (e.g., O₂) or an oxygen- and nitrogen-containing gas (e.g., NO, NO₂, N₂O) and optionally an inert gas such as a noble gas (i.e., helium, neon, argon, xenon, krypton). According to one embodiment of the invention, the process gas can consists of O₂ or O₂ and an inert gas such as a noble gas.

The electromagnetic radiation assembly 530 can, for example, contain an ultraviolet (UV) radiation source. The UV source may be monochromatic or polychromatic. Additionally, the UV source can be configured to produce UV radiation 545 at a wavelength sufficient for dissociating an oxygen-containing gas or an oxygen- and nitrogen-containing gas in the process gas. In one embodiment, the oxygen-containing gas can contain O₂ and the ultraviolet radiation can have a wavelength from about 145 nm to about 192 nm. Other wavelength may be used for other oxygen-containing gases or oxygen- and nitrogen-containing gases. The electromagnetic radiation assembly 530 can operate at a power ranging from about 5 mW/cm² to about 50 mW/cm². The electromagnetic radiation assembly 530 can include one, two, three, four, or more radiation sources. The sources can include lamps or lasers or a combination thereof.

The processing system 500 contains a substrate temperature control system 560 coupled to the substrate holder 520 and configured to elevate and control the temperature of substrate 525. Substrate temperature control system 560 contains temperature control elements, such as a heating system that may contain resistive heating elements, or thermo-electric heaters/coolers. Additionally, substrate temperature control system 560 may contain a cooling system including a re-circulating coolant flow that receives heat from substrate holder 520 and transfers heat to a heat exchanger system (not shown), or when heating, transfers heat from the heat exchanger system. Furthermore, the substrate temperature control system 560 may include temperature control elements disposed in the chamber wall of the process chamber 510 and any other component within the processing system 500.

Furthermore, the process chamber 510 is further coupled to a pressure control system 532, including a vacuum pumping system 534 and a valve 536, through a duct 538, wherein the pressure control system 532 is configured to controllably evacuate the process chamber 510 to a pressure suitable for processing the substrate 525. Moreover, a device for monitoring chamber pressure (not shown) can be coupled to the process chamber 510.

Additionally, the processing system 500 contains a controller 570 coupled to the process chamber 510, vacuum pumping system 534, gas supply system 540, power source 550, and substrate temperature control system 560. Alternatively, or in addition, controller 570 can be coupled to a one or more additional controllers/computers (not shown), and controller 570 can obtain setup and/or configuration information from an additional controller/computer.

The controller 570 can contain a microprocessor, memory, and a digital I/O port capable of generating control voltages sufficient to communicate and activate inputs to processing system 500 as well as monitor outputs from processing system 500. For example, a program stored in the memory may be utilized to activate the inputs to the aforementioned components of the processing system 500 according to a process recipe in order to perform process.

Self-limiting oxidation and/or nitridation of a material on substrate 525 in the processing system 500 can include a substrate temperature between about 200° C. and about 800° C., for example about 700° C. Alternatively, the substrate temperature can be between about 400° C. and about 700° C. The pressure in the process chamber 510 can, for example, be maintained between about 10 mTorr and about 20 Ton, for example about 100 mTorr. Alternatively, the pressure can be maintained between about 20 mTorr and about 1 Torr According to one embodiment of the invention, the process gas consists of O₂ that may be introduced into the process chamber 510 at a flow rate between about 100 standard cubic centimeters per minute (sccm) and about 2 slm. According to another embodiment of the invention, the process gas can consist of O₂ and an inert gas such as a noble gas (i.e., helium, neon, argon, xenon, krypton). A flow rate of the inert gas can, for example, be between 0 slm and about 2 slm, or between 0.1 slm and 1 slm. In one example, the process gas consists of O₂ and Ar. Exemplary gas exposure times are between about 10 seconds and about 5 min, or between about 30 seconds and about 2 minutes, for example about 1 minute.

FIG. 6 is a schematic diagram of another processing system containing a non-ionizing radiation source for performing an oxidation, nitridation, or oxidation and nitridation process according to one embodiment of the invention. The radiation source can be a UV radiation source or a visible light radiation source, for example. The processing system 600 includes a process chamber 681 accommodating therein a rotatable substrate holder 682 equipped with a heater 683 that can be a resistive heater. Alternatively, the heater 683 may be a lamp heater or any other type of heater. Furthermore the process chamber 681 contains an exhaust line 690 connected to the bottom portion of the process chamber 681 and to a vacuum pump 687. The substrate holder 682 can be rotated by a drive mechanism (not shown). The process chamber 681 contains a processing space 686 above the substrate 625. The inner surface of the process chamber 681 contains an inner liner 684 made of quartz in order to suppress metal contamination of the substrate 625 to be processed.

The process chamber 681 contains a gas line 688 with a nozzle 689 located opposite the exhaust line 690 for flowing a process gas containing an oxygen-containing gas, a nitrogen-containing gas, or an oxygen- and nitrogen-containing gas. The process gas is excited by non-ionizing electromagnetic radiation 695, flows over the substrate 625 in a processing space 686 and is evacuated from the process chamber 681 by the exhaust line 690.

The process gas supplied from the nozzle 689 is activated by non-ionizing electromagnetic radiation 695 generated by an electromagnetic radiation source 691 emitting non-ionizing electromagnetic radiation 695 through a transmissive window 692 (e.g., quartz) into the processing space 686 between the nozzle 689 and the substrate 625. The transmissive window 692 separates the electromagnetic radiation source 691 from the reduced pressure processing space 686. The electromagnetic radiation source 691 is configured to generate non-ionizing electromagnetic radiation 695 capable of dissociating the oxygen-containing gas, the nitrogen-containing gas, or the oxygen- and nitrogen-containing gas to form neutral O radicals, neutral N radicals, or neutral O and N radicals, that flow along the surface of the substrate 625, thereby exposing the substrate 625 to the neutral O radicals and/or neutral N radicals. Unlike during plasma processing, substantially no ions are formed in the processing space 686 from dissociation of the oxygen-containing gas, the nitrogen-containing gas, or the oxygen- and nitrogen-containing gas, by the non-ionizing electromagnetic radiation 695. According to one embodiment of the invention, the electromagnetic radiation source 691 is configured to generate UV radiation with a wavelength between about 145 nm to about 192 nm, for example 172 nm. Although only one electromagnetic radiation source 691 is depicted in FIG. 6, other embodiments of the invention contemplate the use of a plurality of electromagnetic radiation sources 691 above the substrate 625.

Furthermore, the process chamber 681 contains a radical generator 693 located opposite the exhaust line 690. The radical generator 693 may be an ozone generator. The radical generator 693 generates vapor phase ozone that may be used to assist in the non-ionizing electromagnetic radiation-assisted oxidation process described above. Alternately, the vapor phase ozone may be used alone without the electromagnetic radiation source 691. Vapor phase ozone from the radical generator 693 flows along the surface of the substrate 625, thereby exposing the substrate 625 to the vapor phase ozone. The processing system 600 is configured to flow O₂ gas from a gas delivery line 694 to radical generator 693 where the O₂ gas is plasma excited to form an O₃+O₂ mixture. An exemplary O₃+O₂ mixture contains about 5% O₃, balance O₂. The radical generator 693 can, for example, contain a microwave frequency generator. The O₃+O₂ mixture, hereafter referred to as O₃, is then introduced into the process chamber 10 and exposed to the substrate 625. According to another embodiment, the radical generator 693 may be used for generating nitrogen radicals from a nitrogen-containing gas.

Still referring to FIG. 6, a controller 699 includes a microprocessor, a memory, and a digital I/O port capable of generating control voltages sufficient to communicate and activate inputs of the processing system 600 as well as monitor outputs from the processing system 600. Moreover, the controller 699 is coupled to and exchanges information with process chamber 681, the vacuum pump 687, the heater 683, the ozone generator 693, and the electromagnetic radiation source 691. The controller 699 may be implemented as a UNIX-based workstation. Alternatively, the controller 699 can be implemented as a general-purpose computer, digital signal processing system, etc.

Next, apparatus and processing method for the oxide, nitride, or oxynitride film removal process of step 18 in FIG. 1 will be described. The oxide, nitride, or oxynitride film removal step can be performed by any method as long as it can preferentially remove an oxide, a nitride, or an oxynitride film formed on a material surface. Accordingly, this method is not limited to a specific method, but may be selected from the following methods, as described above: (1) a wet etching process using diluted hydrofluoric acid, (2) a vapor etching process within a hydrofluoric acid vapor atmosphere, (3) a COR process arranged to apply a reactive gas containing HF and NH₃ onto a silicon oxide film to form a reaction product and then to remove the reaction product by heating, (4) a nitride/oxynitride removal process, and (5) a NOR process.

In a method based on (1), the wet etching process uses diluted hydrofluoric acid with a mixture ratio of about HF:H₂O=1:100 is stored in a wet processing container. A wafer with a silicon oxide film formed thereon is immersed in the diluted hydrofluoric acid for 10 to 600 seconds, or for 60 to 360 seconds, so that the silicon oxide film is removed by chemical etching without damage.

In a method based on (2), the vapor etching process uses a hydrofluoric acid vapor atmosphere and a wafer with a silicon oxide film formed thereon is exposed to hydrofluoric acid vapor generated from HF solution having a concentration of 20%, for example, for 3 to 600 seconds, or for 3 to 300 seconds, inside a process container provided with the an exhaust unit, so that the silicon oxide film is removed by chemical etching without damage.

In a method based on (3), the COR process uses a COR processing apparatus 102, as shown in FIG. 6, such that a reactive gas containing HF and NH₃ is supplied and caused to react with the silicon oxide film, and the reaction product thus produced is removed by heating. As shown in FIG. 7, the COR processing apparatus 102 includes a cylindrical chamber 110 and a worktable 112 disposed inside the chamber 110 to place a wafer W (not shown) thereon. A showerhead 114 is disposed on the upper side of the chamber 110 and an exhaust unit 116 is disposed to exhaust gas or the like from inside the chamber 110. The worktable 112 is provided with an electrode plate (not shown) embedded therein and configured to be supplied with a DC voltage so as to attract and hold the wafer W.

The showerhead 114 has a two-layer structure comprising a first buffer space 118 and a second buffer space 120. The first buffer space 118 and the second buffer space 120 communicate with the inside of the chamber 110 through gas channel holes 122 and 124, respectively. When the COR process is performed on the wafer W, NH₃ (ammonia) gas is supplied from an ammonia gas supply line 126 into the first buffer space 118 and delivered through the gas channel holes 122 into the chamber 110. Further, HF (hydrogen fluoride) gas is supplied from a hydrogen fluoride gas supply line 128 into the second buffer space 120 and delivered through the gas channel holes 124 into the chamber 110.

The COR process conditions may include comprise a reactive gas containing HF and NH₃ with a flow rate ratio of HF/NH₃=0.1 to 2, HF at a flow rate of 5 to 500 mL/min (sccm), and NH₃ at a flow rate of 5 to 500 mL/min (sccm). The process pressure inside the chamber during exposure to the reactive gas can be within a range of 0.1 to 13.3 Pa, or within a range of 0.06 to 6.67 Pa. The process temperature can be between 30 and 500° C., or between 50 to 300° C. Further, Ar gas can be supplied to adjust the partial pressures of HF gas and NH₃ gas. In place of Ar gas, N₂ gas or H₂ gas may be used.

Thereafter, during the step of removing the reaction product by heating, the wafer W with the reaction product formed thereon is heated at a temperature of 50 to 300° C., or 100 to 200° C., for 30 to 360 seconds, or for 100 to 200 seconds, for example.

In a method based on (4), the nitride/oxynitride removal process uses the COR processing apparatus 102, as shown in FIG. 6, such that a reactive gas containing HF and optionally NH₃ is supplied and caused to react with the silicon nitride/oxynitride film, and the reaction product thus produced is removed by heating. The nitride/oxynitride removal process conditions may include comprise a reactive gas containing HF and optionally NH₃, HF at a flow rate of 5 to 500 mL/min (sccm), and optionally NH₃ at a flow rate of 5 to 500 mL/min (sccm). The process pressure inside the chamber during exposure to the reactive gas can be within a range of 0.1 to 13.3 Pa, or within a range of 0.06 to 6.67 Pa. The process temperature can be between 30 and 500° C., or between 50 to 300° C. Further, Ar gas can be supplied to adjust the partial pressures of HF gas and optional NH₃ gas. In place of Ar gas, N₂ gas or H₂ gas may be used. Thereafter, during the step of removing the reaction product by heating, the wafer W with the reaction product formed thereon is heated at a temperature of 50 to 300° C., or 100 to 200° C., for 30 to 360 seconds, or for 100 to 200 seconds, for example.

The present invention is not limited to the embodiments described above, and it may be modified in various manners. For example, in the embodiment described above, a process for fabricating a MOSFET having a three-dimensional structure is described as an example of a process for manufacturing semiconductor devices to which the pattern forming method is applicable. Alternatively, for example, the pattern forming method may be used for applications that require formation of an oxide film of high quality along a rugged pattern, formation of an oxide film inside an STI (Shallow Trench Isolation) trench for a device isolation technique, and formation of the poly-crystalline silicon gate electrode of a transistor. Further, the pattern forming method according to the embodiments of the invention may be applied to a case where a metal gate electrode is formed as well as a case where a poly-crystalline silicon gate electrode is formed in transistors. Further, a substrate to be processed is not limited to a silicon wafer but may be another substrate, such as a compound semiconductor substrate, liquid crystal display (LCD) substrate, or solar battery panel, wherein pattern formation may be performed on single-crystalline silicon, poly-crystalline silicon, or amorphous silicon.

The present invention is not limited to the embodiments described above for thinning patterns and features but may also be applied to a thin film covering large areas of a semiconductor wafer (e.g., 200, 300, or 450 mm Si wafer) or a thin (blanket) film covering the entire upper surface of a Si semiconductor wafer. In one example, embodiments of the invention may be applied to silicon on insulator technology (SOI) which refers to the use of a layered silicon-insulator-silicon substrate in place of conventional silicon substrates in semiconductor manufacturing, especially microelectronics, to reduce parasitic device capacitance and thereby improving performance. SOI-based devices differ from conventional silicon-built devices in that the silicon junction is above an electrical insulator, typically silicon dioxide or sapphire. In one example, the SOI structure can include a substrate, an insulator film on the substrate, and a Si film on the insulator film. The Si film may be grown or deposited directly on the insulator and can have a thickness between approximately 5 nm and approximately 30 nm, for example. However, the initial Si film thickness (e.g., 10 nm) may be larger than the desired final Si film thickness (e.g., 5 nm).

According to one embodiment of the invention, an initial blanket Si film in a SOI structure may be thinned to form a thinned blanket Si film. The method includes providing a substrate including a initial blanket Si film on an insulator film, the initial blanket Si film having a first film thickness, performing a self-limiting oxidation and/or nitridation process on a surface of the initial blanket Si film inside a process chamber of a processing apparatus and thereby forming a silicon oxide, nitride, or oxynitride film on a surface of the initial blanket Si film, where the self-limiting oxidation and/or nitridation process includes exposing the surface of the initial blanket Si film to vapor phase ozone, atomic oxygen generated by non-ionizing electromagnetic (EM) radiation, or atomic nitrogen generated by ionizing or non-ionizing radiation, or a combination thereof. The method further includes removing the silicon oxide, nitride, or oxynitride film, where the film thinning method is arranged to repeatedly perform formation of the silicon oxide/nitride/oxynitride film and removal of the silicon oxide/nitride/oxynitride film so as to form a thinned blanket Si film having a second film thickness that is smaller than the first film thickness of the initial blanket Si film. In non-limiting examples, the first film thickness may be between 10 nm and 30 nm, and the second film thickness may be between 5 nm and 20 nm.

A plurality of embodiments of a pattern forming method have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a substrate is directly on and in immediate contact with the substrate; there may be a second film or other structure between the film and the substrate.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A pattern forming method comprising:
providing a substrate including a material with an initial pattern formed thereon and having a first line width;
performing a self-limiting oxidation, nitridation, or oxidation and nitridation process on a surface of the material inside a process chamber of a processing apparatus and thereby forming an oxide, nitride, or oxynitride film on a surface of the initial pattern, wherein the self-limiting oxidation, nitridation, or oxidation and nitridation process includes exposing the surface of the material to vapor phase ozone, atomic oxygen generated by non-ionizing electromagnetic (EM) radiation, atomic nitrogen generated by ionizing or non-ionizing EM radiation, or a combination thereof; and
removing the oxide, nitride, or oxynitride film,
wherein the pattern forming method is arranged to repeatedly perform formation of the oxide, nitride, or oxynitride film and removal of the oxide, nitride, or oxynitride film so as to form an second pattern having a second line width that is smaller than the first line width of the initial pattern.

2. The method of claim 1, wherein the material contains Si, a Si-containing material, a metal, or a metal-containing material, or a combination thereof.

3. The method of claim 1, wherein removal of the oxide, nitride, or oxynitride film is performed by a wet etching process using diluted hydrofluoric acid.

4. The method of claim 1, wherein removal of the oxide, nitride, or oxynitride film is performed by a vapor etching process within a hydrofluoric acid vapor atmosphere.

5. The method of claim 1, wherein removal of the oxide, nitride, or oxynitride film is performed by exposing the oxide, nitride, or oxynitride film to a reactive gas containing HF and optionally NH₃ to form a reaction product, and then removing the reaction product by heating the substrate.

6. The method of claim 1, wherein removal of the oxide film is performed by generating plasma from a gas containing H and N and thereby generating active species containing H and N, supplying the active species into a process chamber and supplying NF₃ gas into this process chamber and activating NF₃ gas by the active species, exposing the active species containing H, N, and NF₃ to the oxide film to form a reaction product, and then removing the reaction product by heating the substrate.

7. The method of claim 1, wherein the second line width is 20 nm or less.

8. The method of to claim 1, wherein the self-limiting oxidation, nitridation, or oxidation and nitridation process for forming the oxide, nitride, or oxynitride film utilizes a process temperature of 200° C. to 800° C.

9. The method of claim 1, wherein the substrate is a semiconductor device with a three-dimensional structure device.

10. The method of claim 9, wherein the initial pattern includes a silicon fin.

11. A pattern forming method comprising:
providing a substrate including silicon with an initial pattern formed thereon and having a first line width;
performing a self-limiting oxidation, nitridation, or oxidation and nitridation process on a surface of the silicon inside a process chamber of a processing apparatus and thereby forming a silicon oxide, silicon nitride, or silicon oxynitride film on a surface of the initial pattern, wherein the self-limiting oxidation, nitridation, or oxidation and nitridation process includes exposing the surface of the silicon to vapor phase ozone, atomic oxygen generated by non-ionizing electromagnetic (EM) radiation, atomic nitrogen generated by ionizing or non-ionizing EM radiation, or a combination thereof; and
removing the silicon oxide, silicon nitride, or silicon oxynitride film,
wherein the pattern forming method is arranged to repeatedly perform formation of the silicon oxide, silicon nitride, or silicon oxynitride film and removal of the silicon oxide, silicon nitride, or silicon oxynitride film so as to form a second pattern having a second line width that is smaller than the first line width of the initial pattern.

12. The method of claim 11, wherein removal of the silicon oxide, silicon nitride, or silicon oxynitride film is performed by a wet etching process using diluted hydrofluoric acid.

13. The method of claim 11, wherein removal of the silicon oxide, silicon nitride, or silicon oxynitride film is performed by a vapor etching process within a hydrofluoric acid vapor atmosphere.

14. The method of claim 11, wherein removal of the silicon oxide film is performed by exposing the silicon oxide, silicon nitride, or silicon oxynitride film to a reactive gas containing HF and optionally NH₃ to form a reaction product, and then removing the reaction product by heating the substrate.

15. The method of claim 11, wherein removal of the silicon oxide, silicon nitride, or silicon oxynitride film is performed by generating plasma from a gas containing H and N and thereby generating active species containing H and N, supplying the active species into a process chamber and supplying NF₃ gas into this process chamber and activating NF₃ gas by the active species, exposing the active species containing H, N, and NF₃ to the silicon oxide, silicon nitride, or silicon oxynitride film to form a reaction product, and then removing the reaction product by heating the substrate.

16. The method of claim 11, wherein the second line width is 20 nm or less.

17. The method of claim 11, wherein the self-limiting oxidation, nitridation, or oxidation and nitridation process for forming the silicon oxide, silicon nitride, or silicon oxynitride film utilizes a process temperature of 200° C. to 800° C.

18. The method of claim 18, wherein the substrate is a semiconductor device with a three-dimensional structure device.

19. A method of fabricating a semiconductor device comprising:
providing a substrate including a initial blanket Si film on an insulator film, the initial blanket Si film having a first film thickness;
performing a self-limiting oxidation, nitridation, or oxidation and nitridation process on a surface of the initial blanket Si film inside a process chamber of a processing apparatus and thereby forming a silicon oxide, silicon nitride, or silicon oxynitride film on a surface of the initial blanket Si film, wherein the self-limiting oxidation, nitridation, or oxidation and nitridation process includes exposing the surface of the initial blanket Si film to vapor phase ozone, atomic oxygen generated by non-ionizing electromagnetic (EM) radiation, atomic nitrogen generated by ionizing or non-ionizing EM radiation, or a combination thereof; and
removing the silicon oxide, silicon nitride, or silicon oxynitride film,
wherein the method is arranged to repeatedly perform formation of the silicon oxide, silicon nitride, or silicon oxynitride film and removal of the silicon oxide, silicon nitride, or silicon oxynitride film so as to form a thinned blanket Si film having a second film thickness that is smaller than the first film thickness of the initial blanket Si film.

20. The method of claim 19, wherein removal of the oxide, nitride, or oxynitride film is performed by a vapor etching process within a hydrofluoric acid vapor atmosphere.
